(19) United States
(12) Patent Application Publication
(10) Pub. No.: US 2022/0308549 A1
(43) Pub. Date: Sep. 29, 2022

(54) PROCESSING APPARATUS

(71) Applicant: DISCO CORPORATION, Tokyo (JP)

(72) Inventor: Takafumi OMORI, Tokyo (JP)

(21) Appl. No.: 17/655,815

(22) Filed: Mar. 22, 2022

(30) Foreign Application Priority Data
Mar. 25, 2021 (JP) 2021-051949

(51) Int. Cl. G05B 19/402; B23Q 15/12; G06T 7/00; G06T 7/73

(52) U.S. Cl. CPC G05B 19/402; B23Q 15/12; G06T 7/0004; G06T 7/73; G05B 2219/39388; G06T 2207/30148

(57) ABSTRACT

A processing apparatus includes a holding table for holding a workpiece thereon, a processing unit for processing the workpiece held on the holding table, an image capturing unit for capturing an image of the workpiece held on the holding table, and a control unit. The control unit includes a wider image displaying section for combining images of a plurality of adjacent areas that are captured by the image capturing unit into a wider image representing an area wider than the field of vision of the image capturing unit, and displaying the wider image on a display unit, and a target registering section for registering any pattern on each of the devices that is specified in the wider image, as a target for detecting one of the projected dicing lines.

### BACKGROUND OF THE INVENTION

### Field of the Invention

The present invention relates to a processing apparatus.

### Description of the Related Art

Processing apparatuses for processing workpieces along projected dicing lines thereon operate to form processed grooves along the projected dicing lines in the workpieces. After the processing apparatuses have formed the processed grooves in the workpieces, they perform a process called “kerf check” for capturing images of the processed grooves and checking the states and positions of the processed grooves in reference to the captured images (see, for example, Japanese Patent No. 6029271).

### SUMMARY OF THE INVENTION

In a case where a processed groove has a width too large to be included in the field of vision of an image capturing unit, since both widthwise ends of the processed groove are not simultaneously displayed in the captured image at the time of the kerf check process, the operator may possibly fail to recognize a positional shift of the processed grooves and a need to correct the positional shift from the captured image. As such, when a workpiece is to be processed to form such a processed groove therein, it has been customary to replace in advance the lens of the image capturing unit with a lens of lower magnification so that both widthwise ends of the processed groove will be included in the field of vision of the image capturing unit. However, if the lens of the image capturing unit is replaced with a lens of lower magnification in order to cope with one type of workpiece, then, when the processing apparatus is to process a wide variety of types of workpieces, the accuracy of the kerf check process performed on other types of workpieces tends to be lowered.

Further, a processing apparatus for processing a workpiece along projected dicing lines thereon performs a process called “teach” for registering in advance the distance between a target, which represents a characteristic one of patterns of devices formed on a face side of the workpiece, and a projected dicing line, and also performs a process called “alignment” for automatically detecting the position of the projected dicing line when the workpiece is actually processed. In a case where a projected dicing line has a width too large to be included in the field of vision of an image capturing unit, since both widthwise ends of the projected dicing line are not simultaneously displayed in the captured image at the time of the teach process, the operator may possibly fail to recognize the position of the projected dicing line and may possibly register the distance in error. In addition, in a case where a target that is suitable for the alignment process is too large to be included in the field of vision of the image capturing unit, if a range included in the field of vision of the image capturing unit is registered as a target, then erroneous recognition may occur at the time of the alignment process, possibly causing the processing apparatus to cut the workpiece at an erroneous position. The problem may be dealt with by replacing the lens of the image capturing unit with a lens of lower magnification to include the target in the field of vision of the image capturing unit. However, when the processing apparatus is to process a wide variety of types of workpieces, the accuracy of the teach and alignment processes performed on other types of workpieces tends to be lowered.

It is therefore an object of the present invention to provide a processing apparatus that is capable of carrying out a process of registering an imaging target on a workpiece that is too large to be included in the field of vision of an image capturing unit, without replacing the lens of the image capturing unit.

In accordance with an aspect of the present invention, there is provided a processing apparatus for processing a workpiece having a plurality of devices in respective areas demarcated on a face side thereof by a plurality of projected dicing lines, along the projected dicing lines, the processing apparatus including a holding table for holding the workpiece thereon, a processing unit for processing the workpiece held on the holding table, an image capturing unit for capturing an image of the workpiece held on the holding table, and a control unit. In the processing apparatus, the control unit includes a wider image displaying section for combining images of a plurality of adjacent areas that are captured by the image capturing unit into a wider image representing an area wider than the field of vision of the image capturing unit, and displaying the wider image on a display unit, and a target registering section for registering any pattern on each of the devices that is specified in the wider image, as a target for detecting one of the projected dicing lines.

The wider image may include one of the projected dicing lines, and the control unit may further have a projected dicing line registering section for registering the one of the projected dicing lines selected in the wider image as a projected processing position.

The wider image may include a processed groove formed in the workpiece processed by the processing unit, and the control unit may display the wider image on the display unit when the control unit performs a kerf check process to check the quality of the processed groove.

According to the aspect of the present invention, it is possible to perform a process of registering a to-be-imaged object without changing the lens of the image capturing unit even if a workpiece has a to-be-imaged object that is too large to fit in the field of vision of the image capturing unit.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective illustrating a structural example of a processing apparatus according to a first embodiment of the present invention;

FIG. 2 is an enlarged fragmentary plan view of a portion of a workpiece as an object to be processed by the processing apparatus according to the first embodiment;

FIG. 3 is a view illustrating an example of a screen that is displayed when the processing apparatus according to the first embodiment registers a target;

FIG. 4 is a view illustrating an example of an image and a wider image that are displayed when the processing apparatus according to the first embodiment registers the target;

FIG. 5 is a view illustrating an example of a screen that is displayed when the processing apparatus according to the first embodiment registers a projected dicing line;

FIG. 6 is a view illustrating an example of an image and a wider image that are displayed when the processing apparatus according to the first embodiment registers the projected dicing line;

FIG. 7 is a view illustrating an example of a screen for displaying a processed groove on which the processing apparatus according to the first embodiment is to perform a kerf check process;

FIG. 8 is a view illustrating an example of an image and a wider image of the processed groove displayed by the processing apparatus according to the first embodiment; and

FIG. 9 is a perspective illustrating a structural example of a processing apparatus according to a second embodiment of the present invention.

### DETAILED DESCRIPTION OF THE PREFERRED EMBODIMENTS

Preferred embodiments of the present invention will be described in detail hereinbelow with reference to the accompanying drawings. The present invention is not limited to the details of the embodiments described below. The components described below cover those which may easily be anticipated by those skilled in the art and those which are essentially identical to those described above. Further, the arrangements described below can be combined in appropriate manners. Various omissions, replacements, or changes of the arrangements may be made without departing from the scope of the present invention. In the description to be given below, those components that are identical to each other are denoted by identical reference characters, and will be omitted from description.

### First Embodiment

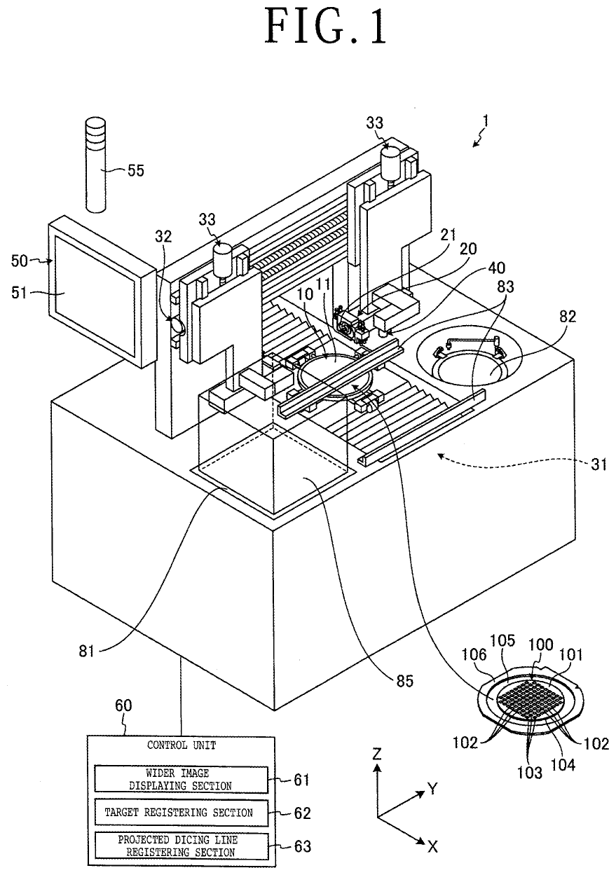

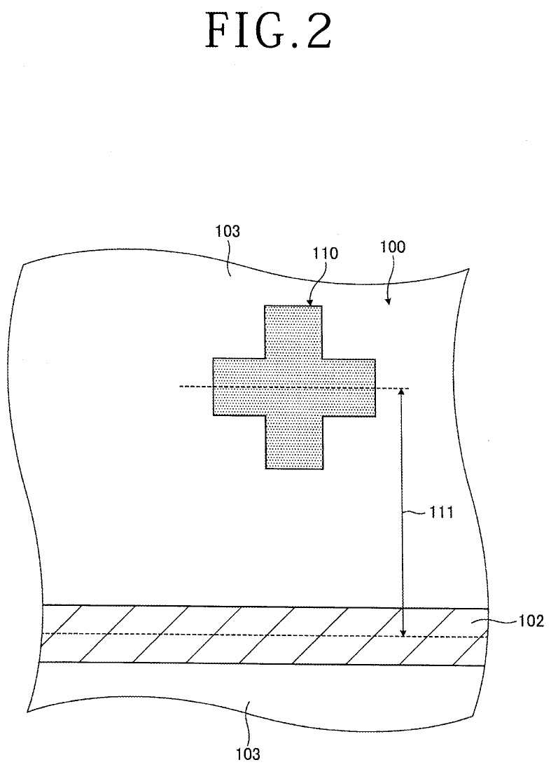

A processing apparatus 1 according to a first embodiment of the present invention will be described below with reference to FIG. 1. FIG. 1 illustrates in perspective a structural example of the processing apparatus 1 according to the first embodiment. FIG. 2 illustrates in enlarged fragmentary plan view a portion of a workpiece 100 as an object to be processed by the processing apparatus 1 according to the first embodiment. As illustrated in FIG. 1, the processing apparatus 1 includes a holding table 10, a pair of processing units 20, an X-axis moving unit 31, a pair of Y-axis moving units 32, a pair of Z-axis moving units 33, a pair of image capturing units 40, a display unit 50, an indicating unit 55, and a control unit 60. The processing units 20 are structurally identical to each other, and hence only one of them will be described below. The Y-axis moving units 32, the Z-axis moving units 33, and the image capturing units 40 are also structurally identical to each other in each pair, and hence only one of them in each pair will be described below.

The workpiece 100 is a semiconductor wafer or an optical device wafer, shaped as a circular plate and made of a base material such as silicon, sapphire, silicon carbide (SiC), gallium arsenide, or glass, for example. As illustrated in FIG. 1, the workpiece 100 has a plurality of devices 103, each of a chip size, formed in respective areas that are demarcated on a flat face side 101 thereof by a plurality of projected dicing lines 102 including those in a first group extending in a first direction and those in a second group extending in a second direction transverse to the first direction. According to the first embodiment, the first and second directions extend perpendicularly to each other, making the projected dicing lines 102 arranged in a grid pattern. According to the present invention, however, the projected dicing lines 102 are not limited to such a pattern. The width of each of the projected dicing lines 102 is larger than the width of the region of a field vision of the image capturing unit 40. According to the first embodiment, the workpiece 100 has a reverse side 104 opposite the face side 101 thereof and affixed to an adhesive tape 105, and an annular frame 106 is mounted on an outer edge portion of the adhesive tape 105, so that the workpiece 100 is supported on the annular frame 106 by the adhesive tape 105. However, the workpiece 100 is not limited to such a structure. According to the present invention, the workpiece 100 may be a rectangular packaged substrate having a plurality of resin-encapsulated devices, a ceramic plate, a glass plate, or the like.

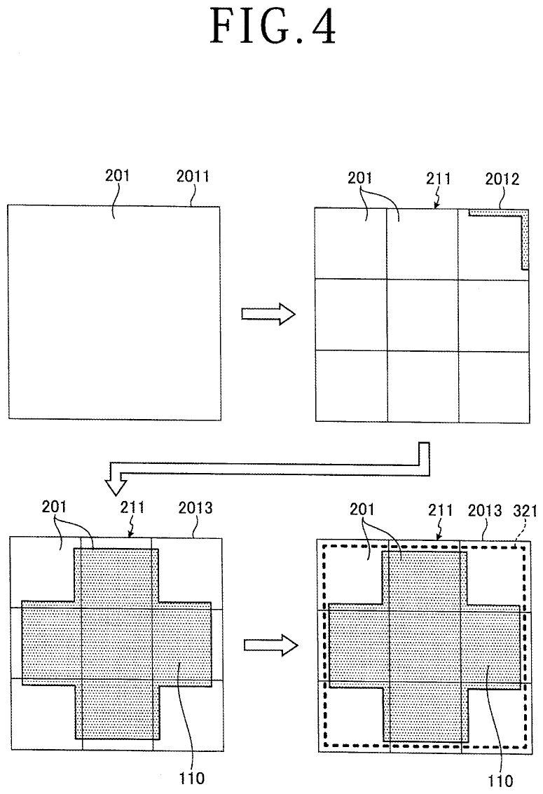

According to the first embodiment, as illustrated in FIG. 2, each of the devices 103 of the workpiece 100 includes a target 110 formed thereon. The target 110 represents an example of any pattern on the device 103 and has a characteristic shape. The target 110 has a planar shape and a color key pattern that can be detected and specified in an image 201 (see FIG. 4) captured by the image capturing unit 40. The target 110 is formed at a position spaced predetermined distances from those projected dicing lines 102 surrounding the device 103 to which the target 110 belongs, and represents a mark for detecting the projected dicing lines 102. In the example illustrated in FIG. 2, the target 110 is spaced from a central line that passes through the widthwise center of the projected dicing line 102 along the first direction, i.e., a horizontal direction in FIG. 2, by a distance 111 along the second direction, i.e., a vertical direction in FIG. 2. According to the first embodiment, the target 110 is larger than the region of the field of vision of the image capturing unit 40.

The holding table 10 includes a disk-shaped frame with a recess defined therein and a disk-shaped suction member fitted in the recess. The suction member of the holding table 10 is made of porous ceramic or the like that has a number of pores therein and is connected to an unillustrated vacuum suction source through an unillustrated vacuum suction channel. The suction member of the holding table 10 has an upper surface functioning as a holding surface 11 for holding under suction the workpiece 100 placed thereon. According to the first embodiment, the workpiece 100 placed on the holding surface 11 has the face side 101 faced and exposed upwardly and the reverse side 104 faced downwardly and held under suction on the holding surface 11 with the adhesive tape 105 interposed therebetween. The holding surface 11 and an upper surface of the frame of the holding table 10 lie flush with each other, and extend along an XY plane defined by X and Y directions parallel to a horizontal plane. The holding table 10 is rotatable about a Z-axis parallel to vertical directions and perpendicular to the XY plane by an unillustrated rotary actuator.

According to the first embodiment, as illustrated in FIG. 1, the processing unit 20 is a cutting unit having a cutting blade 21 mounted on the distal end of a spindle. The processing unit 20 cuts the workpiece 100 held on the holding surface 11 of the holding table 10 with the cutting blade 21 that is rotated by the spindle about its central axis parallel to the Y-axis directions parallel to horizontal directions and perpendicular to the X-axis directions.

The X-axis moving unit 31 moves the holding table 10 relatively to the processing unit 20 along the X-axis directions. The Y-axis moving unit 32 moves the processing unit 20 relatively to the holding table 10 along the Y-axis directions. The Z-axis moving unit 33 moves the processing unit 20 relatively to the holding table 10 along Z-axis directions parallel to the Z-axis. The X-axis moving unit 31 has an unillustrated X-axis position detector for detecting the position of the holding table 10 in the X-axis directions. The X-axis moving unit 31 outputs the position of the holding table 10 in the X-axis directions that is detected by the X-axis position detector to the control unit 60. The Y-axis moving unit 32 and the Z-axis moving unit 33 have an unillustrated Y-axis position detector and an unillustrated Z-axis position detector, respectively, for detecting the respective positions of the processing unit 20 in the Y-axis directions and the Z-axis directions. The Y-axis moving unit 32 and the Z-axis moving unit 33 output the positions of the processing unit 20 in the Y-axis directions and the Z-axis directions that are detected respectively by the Y-axis position detector and the Z-axis position detector to the control unit 60.

The processing apparatus 1 operates to perform a cutting process as follows: The cutting blade 21 of the processing unit 20 is rotated about its central axis by the spindle. At the same time, the X-axis moving unit 31, the Y-axis moving unit 32, and the Z-axis moving unit 33 move the rotating cutting blade 21 to have the cutting blade 21 cut into the workpiece 100 on the holding table 10 and to also move the rotating cutting blade 21 along the projected dicing line 102 that has been registered as a projected processing position by a projected dicing line registering section 63, to be described later, of the control unit 60 in an alignment process carried out prior to the cutting process. As a result, the rotating cutting blade 21 cuts the workpiece 100 along the projected dicing line 102 to form a cut groove, i.e., a processed groove, 120 (see FIG. 8) in the workpiece 100 along the projected dicing line 102. According to the first embodiment, the width of the processed groove 120 is larger than the width of the region of the field vision of the image capturing unit 40.

The image capturing unit 40 includes an unillustrated image capturing device for capturing an image of the face side 101 of the workpiece 100 that is yet to be processed, including the projected dicing lines 102 and the target 110, and also an image of the processed groove 120 formed in the workpiece 100 that has been processed. The image capturing device is, for example, a charge-coupled device (CCD) image sensor or a complementary metal oxide semiconductor (CMOS) image sensor. The image capturing unit 40 captures an image of the region of the field of vision having a predetermined area based on the image capturing device and an unillustrated optical system such as an objective lens, at a predetermined magnification ratio based on the optical system. The optical system of the image capturing unit 40 is a microscope, for example. According to the first embodiment, the image capturing unit 40 is fixed to the processing unit 20 for movement in unison therewith.

The image capturing unit 40 captures an image of the workpiece 100 held on the holding table 10 before the workpiece 100 is processed, and carries out a teach process for registering in advance the image of the workpiece 100 including the target 110 and the distance 111 from the target 110 to the projected dicing line 102. The image capturing unit 40 also obtains an image of the target 110 and the projected dicing line 102 for performing the alignment process for positioning the workpiece 100 and the cutting blade 21 of the processing unit 20 with respect to each other, and outputs the obtained image to the control unit 60. Moreover, the image capturing unit 40 captures an image of the workpiece 100 held on the holding table 10 while the workpiece 100 is being processed or after the workpiece 100 has been processed, obtains the image for performing a kerf check process for automatically checking the quality of the processed groove 120, and outputs the obtained image to the control unit 60.

The display unit 50 is mounted on an unillustrated cover of the processing apparatus 1 with its display surface facing outwardly. The display unit 50 displays a screen for setting cutting conditions for the processing apparatus 1, image capturing conditions for the image capturing unit 40, and various conditions for the teach, alignment, and kerf check processes, images captured by the image capturing unit 40 for performing the teach, alignment, and kerf check processes, a wider image generated by combining or joining the above images with a wider image displaying section 61, to be described later, of the control unit 60, a screen including the images and the wider image, and results of an inspection of the processed groove 120 according to the kerf check process, so that those screens, images, and results can be viewed by the operator. The display unit 50 includes a liquid crystal display device or the like. The display unit 50 incorporates an input unit 51 that can be used by the operator to enter information regarding the conditions referred to above for the processing apparatus 1, information regarding displaying of the images, etc. The input unit 51 is typically a touch panel though it may be a keyboard or the like.

The indicating unit 55 is also mounted on the unillustrated cover of the processing apparatus 1. According to the first embodiment, the indicating unit 55 is a light-emitting unit including light-emitting diodes or the like for indicating the results of the inspection of the processed groove 120 according to the kerf check process, in a visually recognizable manner to the operator through lighting, blinking, and light hues of the light-emitting unit. According to the present invention, however, the indicating unit 55 is not limited to the light-emitting unit. For example, the indicating unit 55 may be an audio unit including a speaker or the like for radiating sounds to indicate the results of the inspection of the processed groove 120 according to the kerf check process, etc., in an aurally recognizable manner to the operator.

In a case where the processing apparatus 1 is connected, via a wired or wireless link, to an information-processing device such as a smartphone, a tablet, a wearable device, or a computer, the display part of the information-processing device may be used as the display unit according to the present invention. In other words, the processing apparatus 1 may display the various images and wider image, the screen, the results of the inspection, etc., referred to above, on the display part of the information-processing device that is connected, via a wired or wireless link, to the processing apparatus 1.

The control unit 60 controls operation of the various components of the processing apparatus 1 to enable the processing apparatus 1 to perform a cutting process on the workpiece 100. The control unit 60 processes any positions on the face side 101 of the workpiece 100 held on the holding surface 11 of the holding table 10 as coordinates in an XY plane established on the holding surface 11 of the holding table 10. The processing apparatus 1 can be set to two directional modes, i.e., a first channel (CH1) and a second channel (CH2), for the workpiece 100. When the processing apparatus 1 is set to the first channel (CH1), the workpiece 100 is held on the holding surface 11 of the holding table 10 such that the first and second directions along which the projected dicing lines 102 extend are aligned with the X-axis directions and the Y-axis directions, respectively, and the coordinates in the first and second directions on the face side 101 of the workpiece 100 are represented by and processed as X coordinates and Y coordinates, respectively. When the processing apparatus 1 is set to the second channel (CH2), the workpiece 100 is held on the holding surface 11 of the holding table 10 such that the second and first directions along which the projected dicing lines 102 extend are aligned with the X-axis directions and the Y-axis directions, respectively, and the coordinates in the second and first directions on the face side 101 of the workpiece 100 are represented by and processed as X coordinates and Y coordinates, respectively.

When the image capturing unit 40 is to capture an image of the region of any field of vision on the face side 101 of the workpiece 100 held on the holding surface 11 of the holding table 10, the control unit 60 acquires the information regarding X and Y coordinates representing the position of the center of the region of the field of vision whose image is to be captured by the image capturing unit 40, in reference to the position in the X-axis directions of the holding table 10 detected by the X-axis position detector and the position in the Y-axis directions of the processing unit 20 detected by the Y-axis position detector. When the cutting blade 21 of the processing unit 20 is to cut the workpiece 100 held on the holding surface 11 of the holding table 10, the control unit 60 acquires the information regarding X and Y coordinates representing the position where the cutting blade 21 is to cut the workpiece 100, in reference to the position in the X-axis directions of the holding table 10 detected by the X-axis position detector and the position in the Y-axis directions of the processing unit 20 detected by the Y-axis position detector. When the projected cutting position where the cutting blade 21 is to cut the workpiece 100 is registered as X and Y coordinates, the control unit 60 makes it possible for the cutting blade 21 to cut the workpiece 100 at the projected cutting position according to the registered X and Y coordinates.

The control unit 60 controls the X-axis moving unit 31 and the Y-axis moving unit 32 to move the image capturing unit 40 relatively to the workpiece 100 that is held on the holding table 10 before the workpiece 100 is processed, thereby causing the image capturing unit 40 to scan a predetermined region on the face side 101 of the workpiece 100. While the control unit 60 is controlling the image capturing unit 40 to successively scan the regions of a plurality of adjacent fields of vision over the face side 101 of the workpiece 100, the control unit 60 controls the image capturing unit 40 to capture and acquire successive images of the regions of the adjacent fields of vision. The control unit 60 associates the acquired images with X and Y coordinates representing the positions of the centers of the regions of the fields of vision of the image capturing unit 40. According to the first embodiment, two adjacent regions are positioned such that an end of one of the regions is aligned with an end of the other region. However, the present invention is not limited to such details. Rather, a portion of one of the regions near an end thereof and a portion of the other region near an end thereof may overlap each other.

As illustrated in FIG. 1, the control unit 60 includes the wider image displaying section 61, a target registering section 62, and the projected dicing line registering section 63. The wider image displaying section 61 combines or joins the images of a plurality of adjacent regions that have been captured by the image capturing unit 40, thereby generating a wider image representing a region wider than the field of vision of the image capturing unit 40, and displays the generated wider image on the display unit 50.

Specifically, the wider image displaying section 61 extracts images of those regions that are adjacent to each other, in reference to X and Y coordinates associated with a plurality of images, and combines the extracted images by joining them, thereby generating a wider image representing a region wider than the field of vision of the image capturing unit 40. The wider image displaying section 61 displays the generated wider image on the display unit 50.

The target registering section 62 registers a target 110 on a device 103 specified in a wider image 211 as a target 110 for detecting a projected dicing line 102. The projected dicing line registering section 63 registers the position of the projected dicing line 102 selected in the wider image 212 as a projected processing position where the cutting blade 21 is to cut the workpiece 100.

According to the first embodiment, the control unit 60 includes a computer system. The computer system includes an arithmetic processing device having a microprocessor such as a central processing unit (CPU), a storage device having a memory such as a read only memory (ROM) or a random access memory (RAM), and an input/output interface device. The arithmetic processing device performs arithmetic processing processes according to computer programs stored in the storage device to generate and output control signals for controlling the processing apparatus 1 through the input/output interface device to various components of the processing apparatus 1.

According to the first embodiment, the wider image displaying section 61 has its functions performed when the arithmetic processing device executes computer programs stored in the storage device. According to the first embodiment, the target registering section 62 and the projected dicing line registering section 63 have their functions performed by the storage device.

As illustrated in FIG. 1, the processing apparatus 1 further includes a cassette rest table 81, a cleaning unit 82, a pair of rails 83, and an unillustrated delivery unit. The cassette rest table 81 supports thereon a cassette 85 as a container for housing a plurality of workpieces 100 therein, and is vertically movable to lift and lower the supported cassette 85 in Z-axis directions. The cleaning unit 82 cleans a workpiece 100 that has been cut by the processing unit 20, to remove foreign matter such as chips attached to the workpiece 100. The unillustrated delivery unit delivers a workpiece 100 between the holding table 10, the cleaning unit 82, the rails 83, and the cassette 85.

The teach process, the alignment process, and the kerf check process that are carried out by the processing apparatus 1 according to the first embodiment will be described below by way of example. When the processing apparatus 1 carries out the teach process, the target registering section 62 of the control unit 60 registers an image of a first target 110, and the projected dicing line registering section 63 of the control unit 60 registers the distance 111 from the first target 110 to a projected dicing line 102 extending along the first direction that is closest to the first target 110. The processing apparatus 1 then turns the holding table 10 through 90 degrees, and the target registering section 62 registers an image of a second target that is different from or the same as the first target 110, and the projected dicing line registering section 63 registers the distance from the second target to a projected dicing line 102 extending along the second direction that is closest to the second target. When the processing apparatus 1 carries out the alignment process, the control unit 60 detects the position of a projected dicing line 102 where the cutting blade 21 is to cut the workpiece 100, by referring as appropriate to the information registered by the target registering section 62 and the projected dicing line registering section 63. Furthermore, the processing apparatus 1 registers the frequency of sessions of the kerf check processes, captures an image of the processed groove 120 at a preset timing, and automatically checks the quality of the processed groove 120.

(Example of the Registration of a Target in the Teach Process Carried Out by the Processing Apparatus)

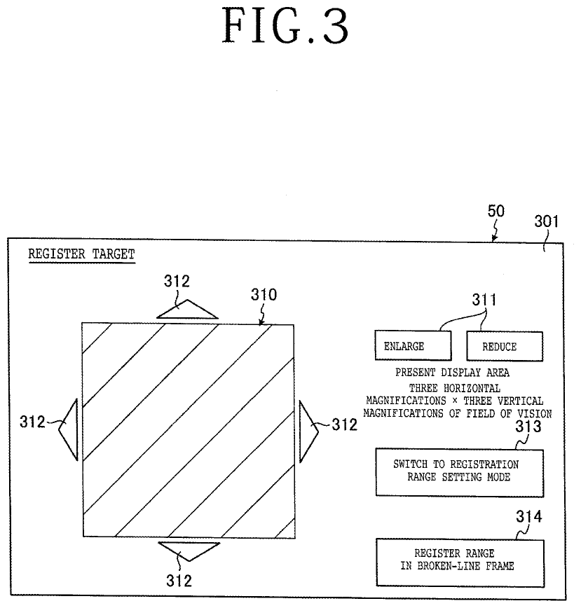

An example of the registration of a target 110 in the teach process carried out by the processing apparatus 1 according to the first embodiment will be described below. FIG. 3 illustrates an example of a screen that is displayed when the processing apparatus 1 according to the first embodiment registers the target 110. FIG. 4 illustrates an example of an image and a wider image that are displayed when the processing apparatus 1 according to the first embodiment registers the target 110.

In order to register the target 110, the control unit 60 of the processing apparatus 1 performs a process of adjusting a display area for a display image such that the target 110 is displayed in its entirety exactly in a display image displayed in an image display area 310 (see FIG. 3) on a screen 301 (see FIG. 3) for target registration that accepts various kinds of input regarding the registration of the target 110. After the process of adjusting the display area for the display image, the control unit 60 of the processing apparatus 1 performs a process of registering an image of the target 110 that is displayed in the display image in the image display area 310 on the screen 301.

According to the first embodiment, the control unit 60 of the processing apparatus 1 initially displays an image of the display area according to an initial setting in the image display area 310. According to the first embodiment, since the initial setting represents one field of vision of the image capturing unit 40, the size of the target 110 is too large to fit in the field of vision of the image capturing unit 40, and the image of the display area displays an image of a portion of the target 110. According to the first embodiment, the control unit 60 establishes an initial setting display area 2011 on the screen 301 for target registration as being identical to the field of vision of the image capturing unit 40. However, the present invention is not limited to such an initial setting display area. Instead, the initial setting display area on the screen 301 may be wider or narrower than the field of vision of the image capturing unit 40.

In the example illustrated in FIG. 3, the screen 301 for target registration includes the image display area 310 for displaying a display image, a pair of display area setting buttons 311 for enlarging or reducing the field of vision of the display image, a plurality of display area moving buttons 312 for moving the field of vision of the display image, a mode switching button 313, and a registration button 314.

The display area setting buttons 311 are buttons for accepting input for setting the size of the display area for a display image displayed in the image display area 310. According to the first embodiment, the display area setting buttons 311 include an enlarging button for accepting input for enlarging the display area and a reducing button for accepting input for reducing the display area, as illustrated in FIG. 3. The image display area 310 displays the size of the display area as compared with the field of vision of the image capturing unit 40, for example, immediately near, i.e., below, the display area setting buttons 311.

The display area moving buttons 312 are buttons for accepting input for moving the display area. According to the first embodiment, as illustrated in FIG. 3, the display area moving buttons 312 include movement buttons for respective directions, i.e., buttons for accepting input for moving the display area in upward, downward, leftward, and rightward directions. The mode switching button 313 is a button for switching between a display area adjustment mode for adjusting the display area and a registration range setting mode for setting a registration range for the target 110 in a display image. The registration button 314 is a button for accepting input for registering the target 110.

According to the first embodiment, the size of the display area is changed by the operator who selects one of the enlarging and reducing buttons as the display area setting buttons 311. According to the present invention, the size of the display area may be changed by other methods. For example, the control unit 60 may enlarge the size of the display area by accepting pinch-out input on a display image displayed in the image display area 310 and reduce the size of the display area by accepting pinch-in input on a display image displayed in the image display area 310. Alternatively, the control unit 60 may enlarge or reduce the size of the display area by accepting numerical input representing a desired size of the display area from the operator.

When the control unit 60 accepts input for enlarging the display area for a display image displayed in the image display area 310 from a size commensurate with one field of vision (one horizontal magnification×one vertical magnification) of the image capturing unit 40 to a size commensurate with nine fields of vision (three horizontal magnifications×three vertical magnifications) of the image capturing unit 40, as illustrated in FIG. 4, for example, the control unit 60 captures images of areas adjacent to the originally displayed image area, combines the captured images to generate a wider image 211 representing a new display area 2012, and displays the wider image 211 in the image display area 310.

According to the first embodiment, the display area for a display image displayed in the image display area 310 is moved when the operator selects the movement buttons for the respective directions as the display area moving buttons 312. The operator can move the display area to a desired area while viewing the display image that is being displayed in the image display area 310. According to the present invention, the display area for a display image displayed in the image display area 310 may be moved by other methods. For example, the control unit 60 may move the display area by accepting swipe input on a display image displayed in the image display area 310 or by accepting numerical input representing a desired distance by which the display area is to be moved, from the operator.

The display area is changed repeatedly until it turns into a display area 2013 representing one target 110 in its entirety, as illustrated in the lower left section of FIG. 4. According to the first embodiment, the wider image displaying section 61 of the control unit 60 captures an image of a new field of vision as the display area changes, to acquire an image 201, and generates and displays a wider image 211. However, the present invention is not limited to such details. Instead, before the display area is changed, the wider image displaying section 61 may combine a plurality of images 201 captured from a range sufficiently wider than the field of vision of the image capturing unit 40, generating in advance a wider image 211 sufficiently wider than the field of vision of the image capturing unit 40, and may change the display area to be displayed in the image display area 310 as the display area changes.

Moreover, in a case where the display area is changed into an area in excess of the area of a plurality of fields of vision whose images have been captured, the wider image displaying section 61 of the control unit 60 may control the image capturing unit 40 to newly capture images 201 of the exceeding area and combine the newly captured images 201 to generate and display a new wider image 211, or may generate and display a wider image 211 in which the exceeding area is displayed in black.

After the display area has been set to the display area 2013 on the screen 301 and adjusted for the display image to display one target 110 exactly in its entirety, when the mode switching button 313 is selected, the screen 301 switches from the display area adjustment mode to the registration range setting mode. In response to the screen 301 switching from the display area adjustment mode to the registration range setting mode, the wider image displaying section 61 of the control unit 60 displays a registration range frame 321 in the display image displayed in the image display area 310, as illustrated in the lower right section of FIG. 4. The screen 301 for target registration may be dispensed with the mode switching button 313, the registration range frame 321 may be displayed at all times in the display image displayed in the image display area 310, and the registration button 314 may be displayed at all times even in a situation where the display area is adjusted.

In the example of the screen 301 illustrated in FIG. 3, the registration range frame 321 is a rectangular frame indicated by broken lines in the lower right section of FIG. 4. The range in the registration range frame 321 is changed when input representative of a dragging action on a frame line, i.e., a side, of the registration range frame 321 is accepted. When the wider image displaying section 61 of the control unit 60 accepts input for changing the range in the registration range frame 321, the wider image displaying section 61 displays a new registration range frame 321 whose range has been changed in the display image displayed in the image display area 310. The control unit 60 repeats this process until there is no longer any input for changing the range in the registration range frame 321, i.e., until it no longer accepts such input.

When there is no longer any input for changing the range in the registration range frame 321 and the target registering section 62 of the control unit 60 accepts the selection of the registration button 314, the target registering section 62 registers the range specified by the registration range frame 321, in the display image displayed in the image display area 310, as an image of the target 110, also registers information regarding the planar shape, color, etc., of the target 110 included in the image thereof together with the registration of the image of the target 110, and further registers the X and Y coordinates of the center of the registration range frame 321 as the position of the target 110.

(Example of the Registration of a Projected Dicing Line in the Teach Process Performed by the Processing Apparatus)

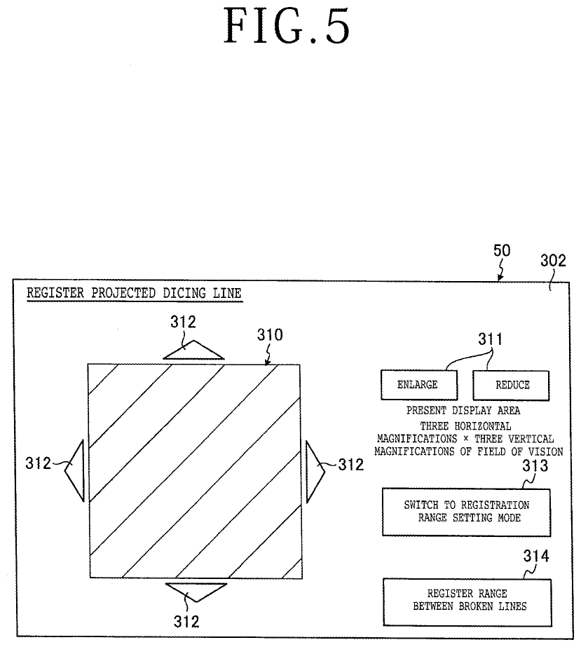

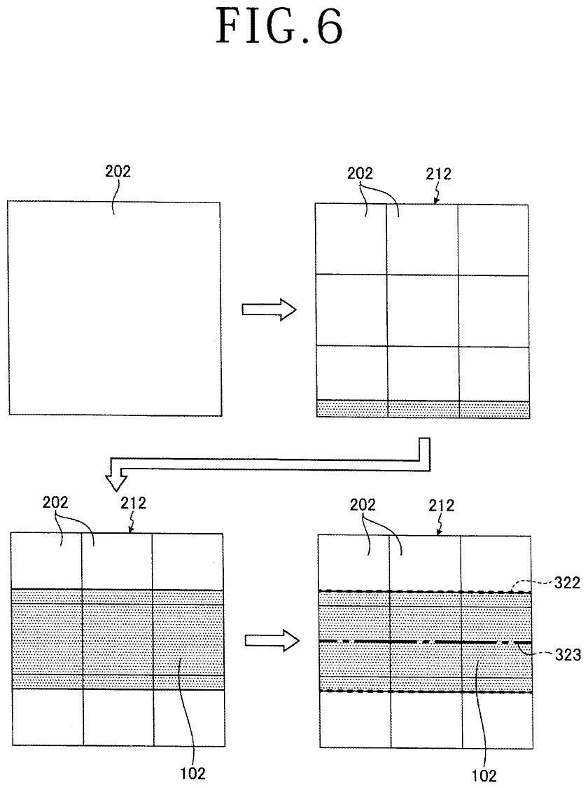

An example of the registration of a projected dicing line 102 in the teach process carried out by the processing apparatus 1 according to the first embodiment will be described below. FIG. 5 illustrates an example of a screen that is displayed when the processing apparatus 1 according to the first embodiment registers the projected dicing line 102. FIG. 6 illustrates an example of an image and a wider image that are displayed when the processing apparatus 1 according to the first embodiment registers the projected dicing line 102.

As with the example of the registration of the target 110, in order to register a projected dicing line 102 extending along the first direction that is closest to the target 110 and a projected dicing line 102 extending along the second direction that is closest to the target 110, the control unit 60 of the processing apparatus 1 performs a process of adjusting a display area for a display image such that a display image displayed in an image display area 310 (see FIG. 5) of a screen 302 (see FIG. 5) for projected dicing line registration that accepts various kinds of input with respect to the registration of a projected dicing line 102 indicates both widthwise ends of the projected dicing line 102 and the central line of the display image is aligned with the central line of the projected dicing line 102. As with the example of the registration of the target 110, after the process of adjusting a display area, the control unit 60 of the processing apparatus 1 performs a process of registering an image of the projected dicing line 102 that is displayed in the display image in the image display area 310 on the screen 302.

In the present description, an example of the registration of a projected dicing line 102 extending along the first direction that is closest to the registered target 110 will be described below. An example of the registration of a projected dicing line 102 extending along the second direction that is closest to the registered second target is similar to the above example except for the direction along which the projected dicing line 102 extends.

The registration of a projected dicing line 102 is different from the registration of a target 110 in that an object to be displayed on the display unit 50 is changed to an area including the projected dicing line 102, but is otherwise similar to the registration of a target 110. As illustrated in FIG. 5, the screen 302 for projected dicing line registration is different from the screen 301 for target registration in that a display image is changed to images, i.e., an image 202 and a wider image 212 (see FIG. 6), including the projected dicing line 102, so that the display on the screen 302 is partly changed. According to the first embodiment, since both widthwise ends of the projected dicing line 102 are not included in the field of vision of the image capturing unit 40, the image displayed in the image display area 310 illustrated in FIG. 5 represents a portion of the projected dicing line 102 according to initial settings.

As illustrated in FIG. 6, after the display image on the screen 302 has been adjusted to represent both widthwise ends of the projected dicing line 102 and to align the central line of the display image with the central line of the projected dicing line 102, when the mode switching button 313 is selected, the screen 302 switches from the display area adjustment mode to the registration range setting mode. The wider image displaying section 61 of the control unit 60 displays a registration range frame 322 and a central line 323 in the display image displayed in the image display area 310. The screen 302 for projected dicing line registration may be dispensed with the mode switching button 313, the registration range frame 322 and the central line 323 may be displayed at all times in the display image displayed in the image display area 310, and the registration button 314 may be displayed at all times even in a situation where the display area is adjusted.

In the example of the screen 302 illustrated in FIG. 5, the registration range frame 322 is a pair of straight lines indicated by broken lines in the lower right section of FIG. 6. In the example of the screen 302 illustrated in FIG. 5, the central line 323 is displayed as a dot-and-dash line midway between the straight broken lines of the registration range frame 322. The wider image displaying section 61 of the control unit 60 displays the central line 323 centrally in a fixed manner in the display image displayed in the image display area 310 and displays the registration range frame 322 in the display image in axial symmetry with respect to the central line 323. The range in the registration range frame 321, i.e., the distance between the straight broken lines of the registration range frame 322, is changed when the wider image displaying section 61 accepts input representative of a dragging action on one of the straight broken lines of the registration range frame 322 in a direction transverse to the straight broken line.

When there is no longer any input for changing the range in the registration range frame 322, i.e., when the projected dicing line registering section 63 of the control unit 60 no longer accepts such input, and the projected dicing line registering section 63 accepts the selection of the registration button 314, the projected dicing line registering section 63 registers the range specified by the registration range frame 322 in the display image displayed in the image display area 310, as an image of the projected dicing line 102, and also registers the Y coordinate of the central line 323, i.e., the coordinate in directions perpendicular to the directions in which the projected dicing line 102 extends, as the position of the projected dicing line 102.

After the projected dicing line registering section 63 has registered the position of the projected dicing line 102 in the first direction, the control unit 60 calculates the distance in the second direction between the target 110 and the central line of the projected dicing line 102 along the first direction, in reference to the difference between the Y coordinate representing the position of the target 110 registered by the target registering section 62 and the Y coordinate representing the position of the projected dicing line 102 in the first direction registered by the projected dicing line registering section 63. The target registering section 62 then registers the calculated distance, denoted by 111 in FIG. 2, as one item of information regarding the target 110.

After having registered the image of the target 110 and the distance 111 from the target 110 to the projected dicing line 102 in the first direction, the control unit 60 turns the holding table 10 through 90 degrees, and then registers an image of the second target and the distance from the second target to the projected dicing line 102 in the second direction according to the same procedure as described above.

An example of the registration of a projected dicing line 102 that is carried out in the alignment process for the workpiece 100 by the processing apparatus 1 according to the first embodiment will be described below. First, the control unit 60 of the processing apparatus 1 acquires an image corresponding to one field of vision of the image capturing unit 40, performs a predetermined pattern matching process, for example, on the acquired image, determines whether or not the image captured in the alignment process is included in the wider image 211 as the target 110 registered by the target registering section 62 in the previously performed teach process, and acquires the position of a target 110 on a new workpiece 100. After having acquired the position of the target 110 on the new workpiece 100, the control unit 60 calculates the position of a projected dicing line 102 in the first direction that is closest to the target 110 on the new workpiece 100, in reference to the position of the target 110 on the new workpiece 100 and the distance 111 registered by the target registering section 62 in the previously performed teach process, and then the projected dicing line registering section 63 registers the calculated position as a projected processing position on the new workpiece 100. The projected dicing line registering section 63 similarly registers the position of a projected dicing line 102 in the second direction as a projected processing position on the new workpiece 100. The control unit 60 then controls the components of the processing apparatus 1 to cut the workpiece 100 along all the projected dicing lines 102 thereof while indexing-feeding the holding table 10 and the cutting blade 21 relatively in one of the Y-axis directions at indexing intervals registered in relation to the registered projected processing position.

(Example of the Kerf Check Process Performed by the Processing Apparatus)

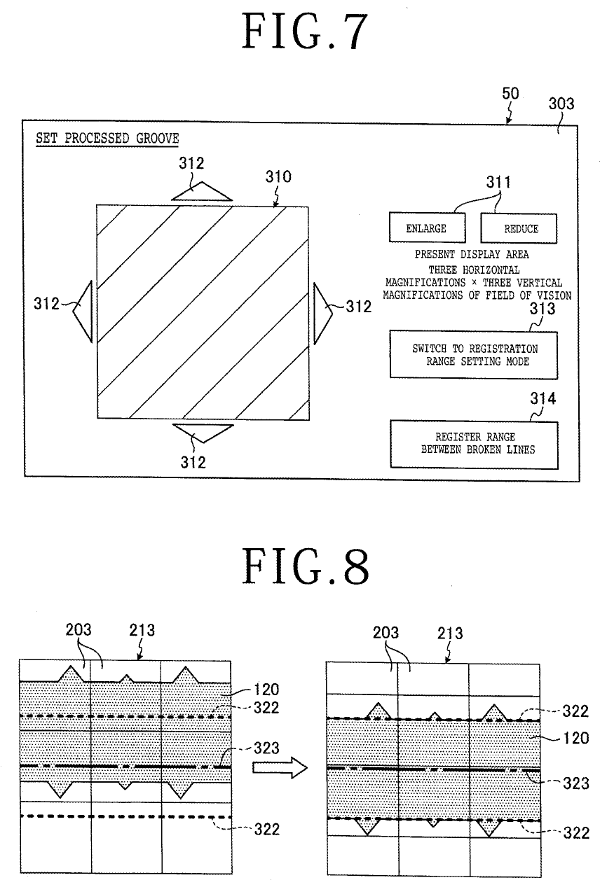

An example of the kerf check process performed by the processing apparatus 1 according to the first embodiment will be described below. FIG. 7 illustrates an example of a screen for displaying a processed groove 120 on which the processing apparatus 1 according to the first embodiment is to perform a kerf check process. FIG. 8 illustrates an example of an image and a wider image of the processed groove 120 displayed by the processing apparatus 1 according to the first embodiment.

The control unit 60 of the processing apparatus 1 performs the kerf check process at a predetermined timing while processing the workpiece 100, and, as illustrated in FIGS. 7 and 8, generates a wider image 213 including both widthwise ends of the processed groove 120 in the same field of vision as that of the wider image 212 used for registering the position of the projected dicing line 102, and displays a screen 303 where the wider image 213 is displayed in the image display area 310 on the display unit 50.

Further, if the processed groove 120 and a hairline representing a projected cutting line recognized by the image capturing unit 40 are shifted from each other by a distance equal to or larger than a threshold value, then the control unit 60 issues an error message. The operator performs a process of aligning the processed groove 120 with the hairline displayed over an image including the processed groove 120, thereby correcting the positional relation between the image capturing unit 40 and the cutting blade 21. At this time, the operator finds it easy to perform the process of aligning the processed groove 120 and the hairline with each other because the wider image 213 including both widthwise ends of the processed groove 120 is displayed, as illustrated in FIG. 8.

Moreover, the control unit 60 detects values of various items to be checked for which the information regarding the both ends of the processed groove 120 is not required, e.g., a chipping width, a maximum chipping width from a kerf end, etc., in reference to original images 203 that make up the wider image 213 including the registered processed groove 120. Then, the control unit 60 checks the quality of the processed groove 120 by determining whether the detected values are acceptable or not. Since the control unit 60 thus performs the kerf check process, when the operator is to correct a cutting position shift, the control unit 60 displays the wider image 213 where both ends of the processed groove 120 are included to prevent an erroneous registration, so that accurate detection and determination are enabled. With respect to the items to be checked that are to be automatically determined by the control unit 60 and that do not require both ends of the processed groove 120 to be included in one screen, highly accurate detection and determination can be made in reference to the original images 203 of high magnification. According to the present invention, even if a workpiece 100 has a to-be-imaged object that is too large to fit in the field of vision of the image capturing unit 40, the to-be-imaged object can be registered without error because a wider image is displayed to display an image of the to-be-imaged object that is too large to fit in the field of vision of the image capturing unit 40 on one screen with respect to manipulative actions requiring decisions by the operator. Consequently, it is possible to perform a process of registering a to-be-imaged object with high accuracy without changing the lens of the image capturing unit 40.

A kerf width represents the distance, i.e., the interval, between both ends of the processed groove 120 in an area to be checked by the kerf check process. The maximum chipping width represents the distance between an end of widthwise maximum chipping in the area to be checked by the kerf check process and an end of the processed groove 120. If the detected value of each of the items to be checked falls within the range of preset allowable values, then the control unit 60 determines that the detected value is acceptable. If the detected value falls outside the range of preset allowable values, then the control unit 60 determines that the detected value is not acceptable, i.e., it is an error.

According to the first embodiment, the operator aligns the processed groove 120 with the hairline according to the kerf check process on the screen 303 while viewing the wider image 213. Yet, the present invention is not limited to such details. Instead, if the shift of the processed groove 120 from the hairline is equal to or smaller than the threshold value, then the processed groove 120 may automatically be established.

In the processing apparatus 1 according to the first embodiment thus arranged, the wider image displaying section 61 of the control unit 60 combines the images 201, 202, and 203 of the adjacent multiple areas that have been captured by the image capturing unit 40, displays the combined images as the wider images 211, 212, and 213 representing areas wider than the field of vision of the image capturing unit 40 on the display unit 50, and registers imaged objects, i.e., the target 110, the projected dicing line 102, and the processed groove 120, specified in the wider images 211, 212, and 213. Therefore, the processing apparatus 1 according to the first embodiment is advantageous in that it can perform a process of registering imaged objects on a workpiece 100 without changing the lens of the image capturing unit 40 even if the imaged objects are too large to be included in the field of vision of the image capturing unit 40.

### Second Embodiment

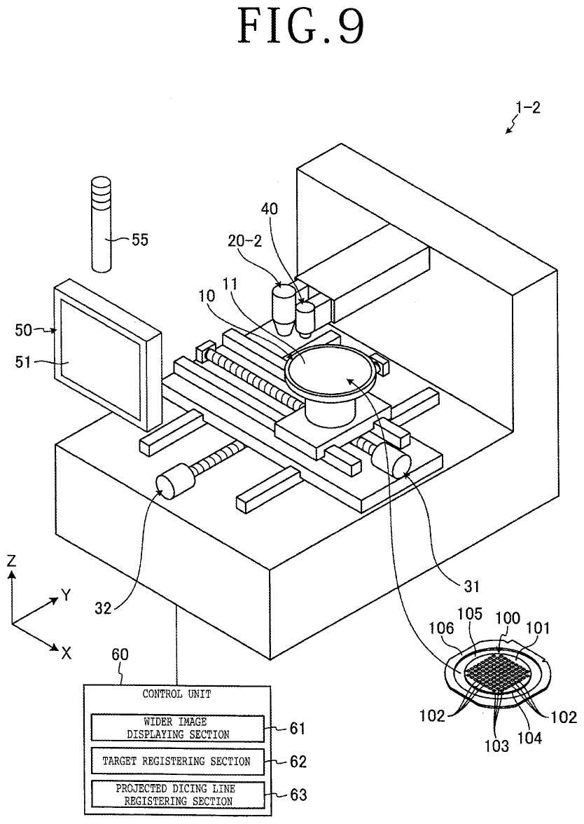

A processing apparatus 1-2 according to a second embodiment of the present invention will be described below with reference to FIG. 9. FIG. 9 illustrates in perspective a structural example of the processing apparatus 1-2 according to the second embodiment. Those parts illustrated in FIG. 9 that are identical to those according to the first embodiment are denoted by identical reference characters, and will be omitted from description.

As illustrated in FIG. 9, the processing apparatus 1-2 according to the second embodiment includes a processing unit 20-2 instead of the processing unit 20 of the processing apparatus 1 according to the first embodiment. According to the second embodiment, as illustrated in FIG. 9, the processing unit 20-2 is a laser processing unit having a laser applying device. The processing unit 20-2 laser-processes, i.e., ablates, a workpiece 100 held on the holding surface 11 of the holding table 10 with a laser beam that is emitted from the laser applying device and that has a wavelength absorbable by the workpiece 100.

According to the second embodiment, the Y-axis moving unit 32 moves the holding table 10 relatively to the processing unit 20-2, and outputs the position in the Y-axis directions of the holding table 10 detected by the Y-axis position detector to the control unit 60. In the second embodiment, the Z-axis moving unit 33 is omitted from illustration in FIG. 9.

The processing apparatus 1-2 according to the second embodiment operates as follows: While the laser applying device of the processing unit 20-2 is applying the laser beam to the workpiece 100 on the holding table 10, the X-axis moving unit 31 and the Y-axis moving unit 32 move the laser applying device as it is emitting the laser beam relatively to the workpiece 100 along the projected dicing line 102 that has been registered as a projected processing position by the projected dicing line registering section 63 in the alignment process prior to the laser processing. As the laser beam emitted from the laser applying device scans the workpiece 100 along the projected dicing line 102, the laser beam laser-processes the workpiece 100 along the projected dicing line 102 to form a processed groove, i.e., a laser-processed groove, 120 in the workpiece 100 along the projected dicing line 102. The processed groove, i.e., the laser-processed groove, 120 formed in the workpiece 100 by the processing apparatus 1-2 according to the second embodiment is the same as the processed groove, i.e., the cut groove, 120 formed in the workpiece 100 by the processing apparatus 1 according to the first embodiment.

The processing apparatus 1-2 according to the second embodiment performs a teach process, an alignment process, and a kerf check process similar to those performed by the processing apparatus 1 according to the first embodiment. Inasmuch as the details of the processing sequences carried out by the control unit 60 in the teach process, the alignment process, and the kerf check process performed by the processing apparatus 1-2 according to the second embodiment are similar to those in the teach process, the alignment process, and the kerf check process performed by the processing apparatus 1 according to the first embodiment, they will be omitted from description below.

Since the control unit 60 of the processing apparatus 1-2 according to the second embodiment thus arranged carries out the same processing sequences in the teach process, the alignment process, and the kerf check process as those according to the first embodiment, the processing apparatus 1-2 according to the second embodiment offers the same advantages as those according to the first embodiment when the processing unit 20-2 laser-processes the workpiece 100 along the projected dicing lines 102 to form the processed grooves 120 in the workpiece 100.

The present invention is not limited to the embodiments described above. Various changes and modifications may be made therein without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus for processing a workpiece having a plurality of devices in respective areas demarcated on a face side thereof by a plurality of projected dicing lines, along the projected dicing lines, comprising:
a holding table for holding the workpiece thereon;
a processing unit for processing the workpiece held on the holding table;
an image capturing unit for capturing an image of the workpiece held on the holding table; and
a control unit,
wherein the control unit includes
a wider image displaying section for combining images of a plurality of adjacent areas that are captured by the image capturing unit into a wider image representing an area wider than a field of vision of the image capturing unit, and displaying the wider image on a display unit, and
a target registering section for registering any pattern on each of the devices that is specified in the wider image, as a target for detecting one of the projected dicing lines.

2. The processing apparatus according to claim 1,
wherein the wider image includes one of the projected dicing lines, and
the control unit further includes a projected dicing line registering section for registering a position of the one of the projected dicing lines selected in the wider image, as a projected processing position.

3. The processing apparatus according to claim 1,
wherein the wider image includes a processed groove formed in the workpiece processed by the processing unit, and
the control unit displays the wider image on the display unit when the control unit performs a kerf check process to check quality of the processed groove.
